(19) United States
(12) Patent Application Publication
(10) Pub. No.: US 2012/0051495 A1
(43) Pub. Date: Mar. 1, 2012

(54) APPARATUS FOR GENERATING CONTROL DATA

(76) Inventors: Jong-Tae HWANG, Seoul (KR); Min-Ho JUNG, Seoul (KR); Jun-Hong LEE, Seoul (KR); Seong-Joon PARK, Seoul (KR)

(21) Appl. No.: 13/110,638

(22) Filed: May 18, 2011

(30) Foreign Application Priority Data
Aug. 25, 2010 (KR) 10-2010-0082352

(51) Int. Cl. H03K 23/00

(52) U.S. Cl. 377/118

(57) ABSTRACT

An apparatus configured to generate control data. The apparatus includes a counter unit configured to receive an input signal having a first state and a second state and counts the first state in the input signal, a delay unit configured to delay the count value for a predetermined time, and a data output unit configured to receive the delayed count value from the counter unit and then generate the control data based on the delayed count value.

The present invention claims priority to Korean Patent Application No. 10-2010-0082352 (filed on Aug. 25, 2010), which is hereby incorporated by reference in its entirety.

### BACKGROUND

A single wire protocol defines a method for controlling a device using a single signal line. The single wire protocol is mainly used for systems that do not require advanced control and high-speed data transmission.

FIG. 1 is a timing diagram that illustrates the use of a typical single wire serial interface for an integrated circuit (IC). FIG. 1 illustrates the relationship among an EN/SET signal, an Enable signal, a Clock signal, a Counter signal, a Latch signal, and a Control Word signal in a signal wire serial interface of an integrated chip, which is disclosed in U.S. Patent Publication No. 2007/0038879. As illustrated, a latch driver maintains the Latch signal in a high state when the EN/SET signal remains in a high state for longer than a Latch Timeout period. The latch driver drops the Latch signal to a low state and maintains the Latch signal in the low state when the EN/SET signal remains in a low state for a duration that exceeds a predefined Timeout period. Thus, values accumulated in a counter are sequentially transmitted to a ROM while the Latch signal remains in the high state. It may cause generating a Control Word “n”.

### SUMMARY

Embodiments relate to a control data generator capable of generating control data using a count value of an input signal each time the input signal is counted.

Embodiments relate to a control data generator configured to sequentially count, store, and output control data included in an input pulse signal.

In accordance with embodiments, an apparatus configured to generate control data which is applied to a single wire protocol, the apparatus including at least the following: a counter unit configured to receive an input signal having a first state and a second state and then count the first state in the input signal, a delay unit configured to delay the count value for a predetermined time; and a data output unit configured to receive the delayed count value from the counter unit and then generate the control data based on the delayed count value.

The counter unit may be reset when the first state of the input signal is maintained for a predetermined time. The counter unit may be reset to a predetermined value based on the number of counted bits. The counter unit may be reset to a predetermined value other than an initial value given when the counter unit starts the counting. The reset value of the counter unit may be based on a final count value of the counter unit. The counter unit may perform counting when the input signal is transited from the second state to the first state. The first state may have one of both a high level and a low level, and the second state has the other level. The counter unit may be an N-bit counter, and the data output unit may be an N-bit command register.

In accordance with embodiments, an apparatus configured to generate control data may include at least the following: a counter unit configured to sequentially count and output control data included in an input pulse signal; and a data output unit configured to sequentially load, store, and output the control data from the counter unit.

The apparatus may further include a delay unit configured to delay the count value of the counter unit for a predetermined time in order to control the data output unit to receive the count value after the predetermined time. The counter unit may be reset to a reset value based on a final count value of the counter unit at the completion of the counting.

In accordance with embodiments, an apparatus configured to generate control data can include at least the following: a maintenance signal detector configured to detect a maintenance signal included in an input signal, an end signal detector configured to detect an end signal included in the input signal, a drive signal unit configured to generate a drive signal when one of the input signal and the end signal is detected, a counter unit configured to receive the input signal having a high state and a low state, count the high state of the input signal in response to the generated drive signal from the drive signal unit, and then generate a count value based on the counting result, a delay unit configured to receive the count value from the counter unit and then delay the received count value for a predetermined time, and a data output unit configured to receive the delayed count value from the delay unit and then generate the control data based on the delayed count value.

The maintenance signal may be a signal remaining in a high state for a predetermined duration and has the high state when the maintenance signal is applied to the apparatus. The end signal may be a signal remaining in a low state for a predetermined duration and has the low state when the end signal applied to the apparatus.

The drive signal unit may generate the drive signal having the high state to activate the counter unit when the input signal transits from the low state to the high state for first time. The drive signal unit may transit the drive signal from the high state to a low state to inactivate the counter unit when the end detector detects the end signal.

The counter unit may transmit the count value to the data output unit in order to change the control data only when the counter value is changed. The counter unit may be activated in response to the drive signal having the high state and counts one of rising edges and high levels of the input signal. The counter unit may reset a previously generated count value to a predetermined value determined based on a number of counted bits when one of the maintenance signal and the end signal is detected.

The data output unit may maintain the control data until the counter unit newly generates the count value when the maintenance detector detects the maintenance signal. The data output unit may initialize the control data when the end detector detects the end signal.

In accordance with embodiments, it is possible to generate and output the count value for the input signal as control data at the time of each counting, allowing application to a serial interface requiring instantaneousness from the single wire protocol.

The count value is reset to a value based on the number of counted bits when the count value is reset, for example, to a value other than an initial value given when the counter unit starts counting, such that control data is generated in a wide range. It is possible, therefore, to secure a wide control range.

### DRAWINGS

FIG. 1 is a timing diagram that illustrates the use of a typical single wire serial interface;

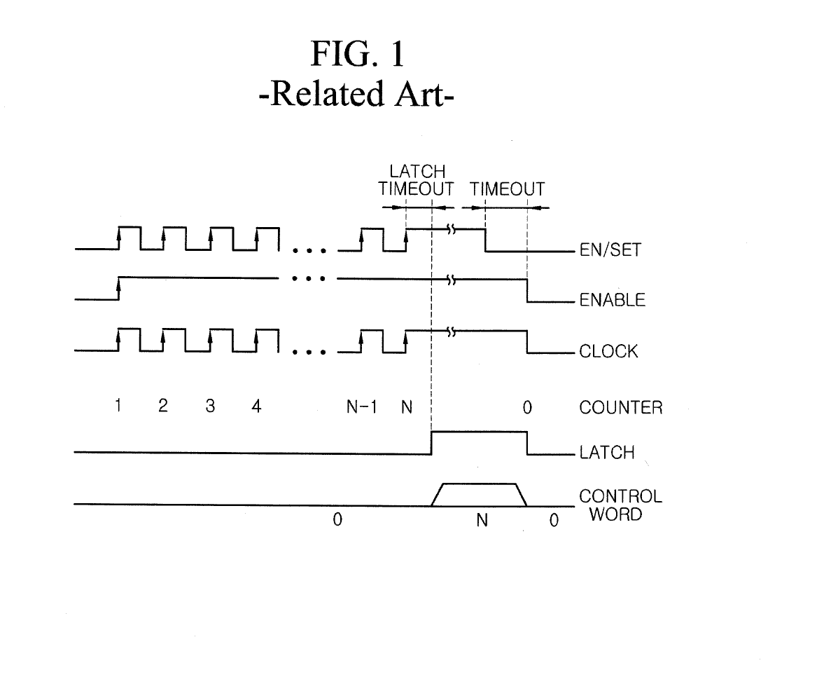

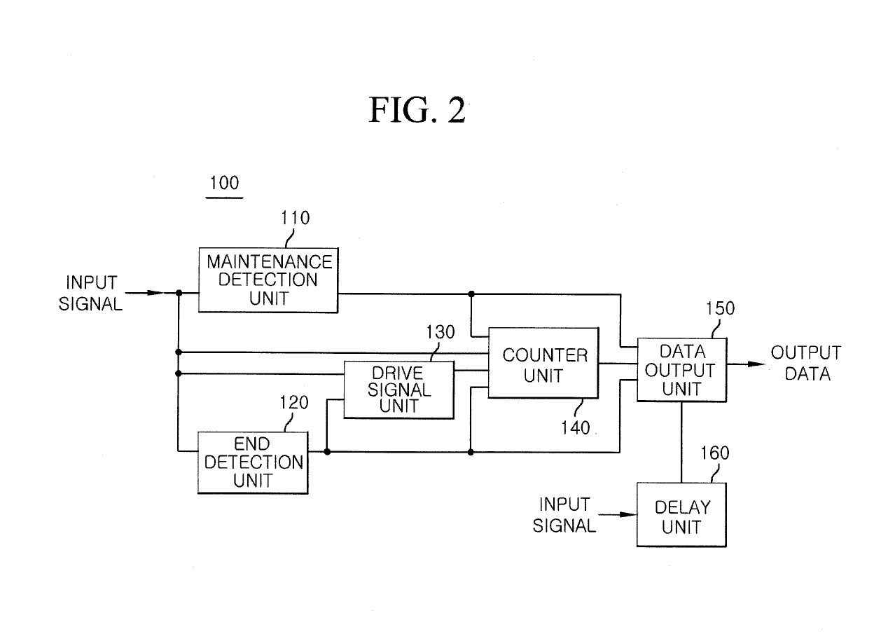

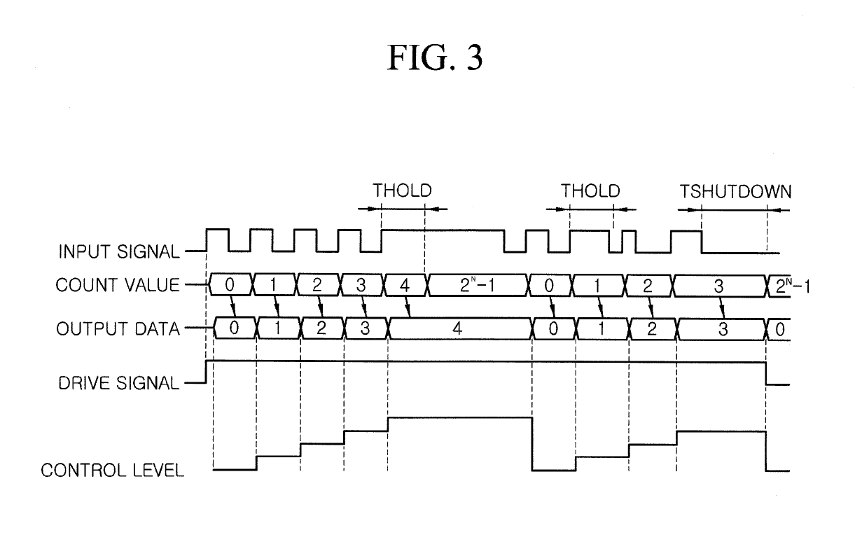

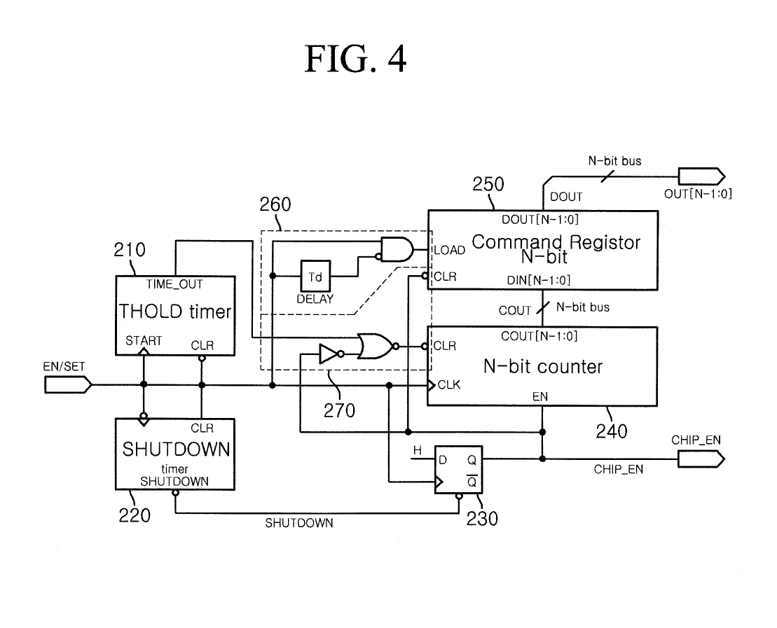

Example FIG. 2 is a block diagram that illustrates a control data generator in accordance with embodiments.

Example FIG. 3 is a timing diagram that illustrates the operation of the control data generator in accordance with embodiments.

Example FIG. 4 is a block diagram that illustrates a control data generator in accordance with embodiments.

### DESCRIPTION

A control data generator in accordance with embodiments will be described in detail with reference to the accompanying drawings.

As illustrated in example FIG. 2, a control data generator 100 may include a maintenance detection unit 110, an end detection unit 120, a drive signal unit 130, a counter unit 140, a data output unit 150, and a delay unit 160.

The maintenance detection unit 110 detects a maintenance signal included in an input signal. The maintenance signal may be a signal remaining in a high state for a predetermined duration. When the input signal is a pulse signal, the maintenance signal may be a signal remaining in a high state for predetermined duration equal to and/or longer than a half period of the pulse signal. For example, when a maintenance signal is applied to a device including a phase inverter the maintenance signal has a low state, not a high state.

The end detection unit 120 detects an end signal included in the input signal. The end signal may be a signal remaining in a low state for a predetermined time period. For a pulse signal, the end signal may be a signal remaining in a low state for predetermined duration equal to or longer than the half period of the pulse signal. For example, when an end signal is applied to a device including a phase inverter, the end signal may remain in a high state, not in a low state. That is, the end signal may remain in a low state or a high state for a time period longer than that of the maintenance signal.

The drive signal unit 130 generates a drive signal depending on the detection of the input signal or the end signal. For example, when the input signal transits from a low state to a high state for the first time, the drive signal unit 130 generates a drive signal having a high state in order to activate a predetermined unit such as the counter unit 140. When the end detection unit 120 detects an end signal, the drive signal unit 130 may transit a drive signal from a high state to a low state in order to inactivate a predetermined unit such as the counter unit 140.

The counter unit 140 sequentially counts and then outputs control data included in the input pulse signal. Further, the counter unit 140 receives an input signal having a first state and a second state and counts the first state in response to the drive signal. Based on the counting result, the counter unit 140 generates a count value. The first state is different from the second state. Furthermore, the counter unit 140 resets the count value at the detection of the maintenance signal by the maintenance detection unit 110 and/or at the detection of the end signal by the end detection unit 120. For example, the counter unit 140 may perform counting when the input signal is transited from the second state to the first state. The counter unit 140 may count rising edges or high levels included in the input pulse signal in order to generate the count value. The counter unit 140 may set the count value to a predetermined value based on the number of counted bits at the detection of the maintenance signal and/or at the detection of the end signal. The count value may be reset to a value other than an initial value at which counting starts. In accordance with embodiments, the reset value may be the final count value 2^{N}−1 (where N is the number of counted bits).

The data output unit 150 sequentially loads, stores, and then outputs the control data from the counter unit 140. Specifically, the data output unit 150 receives the count value of the input signal from the counter unit 140 and outputs the control data based on the count value. The data output unit 150 may receive the count value each time the counter unit 140 performs counting and generate the control data based on the count value from the counter unit 140. When the maintenance detection unit 110 detects a maintenance signal, the data output unit 150 maintains the control data until the counter unit 140 newly generates the count value. When the end detection unit 120 detects the end signal, the data output unit 150 initializes the control data. For example, when the end signal is detected, the data output unit 150 may initialize the control data to “0.”

The delay unit 160 delays the count value received from the counter unit 140 for a predetermined time. Since the delay unit 160 delays the count value, the data output unit 150 receives the delayed count value. Meaning, a time period from when the counter unit 140 generates the count value for the input signal until the data output unit 150 generates the output data is delayed for a predetermined time period.

Example FIG. 3 is a timing diagram that illustrates the operation of the control data generator in accordance with embodiments Operation of a control data generator in accordance with embodiments will be described with reference to example FIGS. 2 and 3. The operation will be described under assumption that an input signal is a pulse signal.

When a pulsed input signal is transited from a low state to a high state for the first time, the drive signal unit 130 generates a drive signal having a high state to activate a predetermined unit to be controlled. As illustrated above, the counter unit 140 is activated in accordance with the drive signal of the high state. The counter unit 140 counts rising edges in the input signal and generates a count value. The counter unit 140 provides the generated count value to the data output unit 150.

The data output unit 150 receives the count value from the counter unit 140 and generates output data, i.e., control data correspondingly. The data output unit 150 loads the count value to generate the control data only after the data output unit 150 receives a data load signal from the delay unit 160. The delay unit 160 delays the data load signal for a predetermined time period corresponding to the time from when the counter unit 140 generates the count value until the data output unit 150 generates the control data. The counter unit 140 transmits the count value to the data output unit 150 in order to change the control data only when the counter value is changed. That is, since the count value changed depending on the change in the input signal needs to be reflected in the control data, the counter value of the counter unit 140 is loaded to the data output unit 150.

After the delay time period set by the delay unit 160, the data output unit 150 generates the control data corresponding to the count value of the counter unit 140. Accordingly, a control level of the control data is changed in real time in accordance with the changes in the count value and the control data.

Meanwhile, if the input signal remains in the high state for a predetermined time (THOLD), the maintenance detection unit 110 recognizes and detects the maintenance signal. Furthermore, the counter unit 140 resets the count value previously generated when the maintenance detection unit 110 informs the counter unit 140 of detection of the maintenance signal. For example, the counter unit 140 resets the count value not to “0” but to “2^{N}−1” (where N is the number of counted bits). This assures the count value to be changed to “0” for counting at the time when the new rising edge of the pulsed input signal is subsequently detected. That is, the count value is rendered in the range of “0” to “2^{N}−1”, so that the control range is maximized.

As described hereinabove, even when the counter unit 140 is reset, the data output unit 150 is not initialized, and the control data is continuously retained as it is. If the counter unit 140 supplies the count value obtained by counting the new rising edge in the input signal, the control data is initialized to “0” at last. That is, the data output unit 150 receives the count value of the input signal from the counter unit 140, generates the control data corresponding to the count value, and retains the control data until the maintenance detection unit 110 detects the maintenance signal. Then, the counter unit 140 newly generates a count value.

If the input signal remains in the low state for a certain time period, for example, for a time period (TSHUTDOWN) longer than the length of the maintenance signal, the end detection unit 120 recognizes and detects the relevant signal as the end signal. Then, when the driver signal unit 130 receives the end signal, the drive signal unit 130 changes the drive signal from the high state to the low state in order to stop the operation of a predetermined unit. Further, the counter unit 140 resets the count value to 2^{N}−1 (where N is the number of counted bits), and the data output unit 150 initializes the control data to “0”.

As illustrated in example FIG. 4, the control data generator may include a first timer 210, a second timer 220, a memory device unit 230, a counter unit 240, a register unit 250, a delay unit 260, and an initialization unit 270.

For the purpose of easy understanding, in comparison between embodiments illustrated in example FIG. 2 and embodiments illustrated in example FIG. 4, it can be seen that the maintenance detection unit 110 substantially corresponds to the first timer 210, the end detection unit 120 substantially corresponds to the second timer 220, the drive signal unit 130 substantially corresponds to the memory device unit 230, the counter unit 140 substantially corresponds to the counter unit 240, the data output unit 150 substantially corresponds to the register unit 250, and the delay unit 160 substantially corresponds to the delay unit 260 in their functions as will be discussed below. The initialization circuit 270 is provided by combining the reset function performed by the counter unit 140 and the initialization function performed by the data output unit 150.

The counter unit 240 may be implemented by an N-bit counter. The counter circuit 240 counts the number of rising edges of a pulsed input signal that inputs to a CLK port through an EN/SET terminal of the control data generator. The counter circuit 240 generates an N-bit COUT signal as an output signal. The counter circuit 240 is reset when a CHIP_EN signal serving as a drive signal is at a low level or when no rising edge is input during the maintenance signal period (THOLD time).

The register circuit 250 may be implemented by an N-bit command register. The register unit 250 receives an N-bit COUT signal from the counter circuit 240 through its DIN port and generates and outputs an N-bit DOUT signal through its DOUT port. The N-bit COUT signal is reflected in the N-bit DOUT signal only when a rising edge occurs in the input signal on the EN/SET terminal. In order to reflect the N-bit COUT signal which has been changed on a basis of the input signal, the delay unit 260 is configured to reflect the N-bit COUT signal in the DIN terminal after a delay time (Td) sufficiently longer than the time period for which the N-bit COUT signal has been changed on a basis of the input signal. If the CHIP_EN signal serving as a drive signal is at the low level, the N-bit DOUT signal is initialized to “0”.

The first timer 210 is also referred to as a THOLD timer. The first timer 210 may be implemented by a maintenance signal timer. If the rising edge occurs in the input signal on the EN/SET terminal, the first timer 210 is activated and starts to time. If another rising edge is not detected for a predetermined time period longer than the maintenance signal period (THOLD time), the first timer 210 generates and outputs a TIME_OUT signal through its TIME_OUT port. Here, the TIME_OUT signal may indicate maintenance signal detection. In response to the TIME_OUT signal, the initialization unit 270 resets the counter circuit 240. If the EN/SET terminal is in the low state, the first timer 210 stops to time and resets the counted value.

The second timer 220 is also referred to as a SHUTDOWN timer. The second timer 220 may be implemented by an end signal timer. If the falling edge occurs in the input signal on the EN/SET terminal, the second timer 220 resets a previously count value and starts to time again. Thus, the time count by the second timer 220 is continued as long as the input signal on the EN/SET terminal remains in the low state. When the low state remains for longer than an end signal period (TSHUTDOWN), the second timer 220 produces and outputs a SHUTDOWN signal through its SHUTDOWN terminal. Here, the SHUTDOWN signal may indicate end signal detection. Usually, the SHUTDOWN signal has a high state as a default state.

The memory device circuit 230 may be implemented by a D flip-flop and is used to generate the CHIP_EN signal serving as a drive signal. If the input signal on the EN/SET terminal is in the high state, the CHIP_EN signal is in the high state unconditionally. If the SHUTDONW signal, however, is transited from the high state to the low state, the memory device unit 230 is reset and the CHIP_EN signal serving as a drive signal becomes in the low state.

The control data generator in accordance with embodiments determines the control data when detecting the rising edge of the input signal. When a riding edge of an input signal is not detected during the maintenance signal period (THOLD), the control data generator may generate control data having a final value. When new rising edge of an input signal is detected, the control data generator may determine the control data again, accordingly.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus configured to generate control data, the apparatus comprising:
a counter unit configured to receive an input signal having a first state and a second state and then count the first state in the input signal;
a delay unit configured to delay the count value for a predetermined time; and
a data output unit configured to receive the delayed count value from the counter unit and then generate the control data based on the delayed count value.

2. The apparatus of claim 1, wherein the counter unit is reset when the first state of the input signal remains for a predetermined time.

3. The apparatus of claim 2, wherein the counter unit is reset to a predetermined value based on a number of counted bits.

4. The apparatus of claim 2, wherein the counter unit is reset to a predetermined value other than an initial value given when the counter unit starts the counting.

5. The apparatus of claim 4, wherein the reset value of the counter unit is determined based on a final count value of the counter unit.

6. The apparatus of claim 1, wherein the counter unit performs counting when the input signal is transited from the second state to the first state.

7. The apparatus of claim 6, wherein the first state has one of a high level and a low level, and the second state has the other level.

8. The apparatus of claim 7, wherein the counter unit is an N-bit counter, and the data output unit is an N-bit command register.

9. An apparatus for generating control data, the apparatus comprising:
a counter unit configured to count and output control data included in an input pulse signal; and
a data output unit configured to load, store, and output the control data from the counter unit.

10. The apparatus of claim 9, further comprising:
a delay unit configured to delay a count value of the counter unit for a predetermined time in order to control the data output unit to receive the count value after the predetermined time.

11. The apparatus of claim 10, wherein the counter unit is reset to a predetermined reset value determined based on a final count value of the counter unit at the completion of the counting.

12. An apparatus for generating control data, comprising;
a maintenance signal detector configured to detect a maintenance signal included in an input signal;
an end signal detector configured to detect an end signal included in the input signal;
a drive signal unit configured to generate a drive signal when one of the input signal and the end signal is detected;
a counter unit configured to receive the input signal having a high state and a low state, count the high state of the input signal in response to the generated drive signal from the drive signal unit, and then generate a count value based on the counting result;
a delay unit configured to receive the count value from the counter unit and then delay the received count value for a predetermined time; and
a data output unit configured to receive the delayed count value from the delay unit and then generate the control data based on the delayed count value.

13. The apparatus of claim 12, wherein:
the maintenance signal is a signal remaining in a high state for a predetermined duration and has the high state when the maintenance signal is applied to the apparatus, and
the end signal is a signal remaining in a low state for a predetermined duration and has the low state when the end signal applied to the apparatus.

14. The apparatus of claim 12, wherein the drive signal unit generates the drive signal having the high state to activate the counter unit when the input signal transits from the low state to the high state for a first time.

15. The apparatus of claim 12, wherein the drive signal unit transits the drive signal from the high state to a low state to inactivate the counter unit when the end detector detects the end signal.

16. The apparatus of claim 12, wherein the counter unit transmits the count value to the data output unit in order to change the control data only when the counter value is changed.

17. The apparatus of claim 12, wherein the counter unit is activated in response to the drive signal having the high state and counts one of rising edges and high levels of the input signal.

18. The apparatus of claim 12, wherein the counter unit resets a previously generated count value to a predetermined value determined based on a number of counted bits when one of the maintenance signal and the end signal is detected.

19. The apparatus of claim 12, wherein the data output unit maintains the control data until the counter unit generates the count value when the maintenance detector detects the maintenance signal.

20. The apparatus of claim 12, wherein the data output unit initializes the control data when the end detector detects the end signal.
